(19) United States
(12) Patent Application Publication
(10) Pub. No.: US 2010/0193848 A1
(43) Pub. Date: Aug. 5, 2010

(54) IMAGE SENSOR OF STACKED LAYER STRUCTURE AND MANUFACTURING METHOD THEREOF

(75) Inventor: Byoung-Su Lee, Yeosu-si (KR)

Correspondence Address: Jae Y. Park, Kile, Goekjian, Reed & McManus, PLLC, 1200 New Hampshire Ave. NW, Suite 570, Washington, DC, 20036, US

(73) Assignee: SILICONFILE TECHNOLOGIES INC., Seoul (KR)

(21) Appl. No.: 12/601,636

(22) PCT Filed: Jun. 9, 2008
(86) PCT No.: PCT/KR2008/003191

§ 371 Date: Nov. 24, 2009

(30) Foreign Application Priority Data
Jun. 8, 2007 (KR) 10-2007-0055761

(51) Int. Cl. H01L 31/0232; H01L 31/113

(52) U.S. Cl. 257/294; 438/59; 257/E31.127; 257/E31.085

(57) ABSTRACT

Provided is a stacked image sensor. Particularly, provided are a stacked image sensor including a photosensitive element portion having a photo-conductive thin film on an upper portion of a wafer where a peripheral circuit is formed and a method of manufacturing the stacked image sensor. In the stacked image sensor according to the present invention, since a wafer where a circuit is formed and a photosensitive element portion are formed in a stacked structure, a whole size of the image sensor can be reduced, and there is no optical crosstalk due to absorption of incident light to adjacent pixels. In addition, since a photo-conductive element having a high light absorbance is used, a high photo-electric conversion efficiency can be obtained. In addition, in the method of manufacturing a stacked image sensor according to the present invention, since the upper photosensitive element can be formed by using a simple low-temperature process, a production cost can be reduced.

### BACKGROUND OF THE INVENTION

1. Field of the Invention

The present invention relates to a stacked image sensor, and more particularly, to a stacked image sensor including a photosensitive element portion having a photo-conductive thin film on an upper portion of a wafer where a peripheral circuit is formed and a method of manufacturing the stacked image sensor.

2. Description of the Related Art

A stacked image sensor is a sensor where a photo-sensitive element such as a photodiode and peripheral circuits such as MOS (Metal Oxide Semiconductor) transistors are formed in a stacked structure.

Since the photosensitive element such as a photodiode is disposed in an upper portion of the image sensor, a path of incident light in the stacked image sensor becomes short. Therefore, there is no optical crosstalk due to interference between adjacent pixels. Since a photodiode region and a MOS transistor region are disposed in the stacked structure, a size of the image sensor can be reduced, and a high photo-electric conversion efficiency can be obtained.

FIG. 1 is a schematic view illustrating a structure of a conventional stacked image sensor.

There have been proposed various methods of manufacturing the stacked image sensor. In an example of the method, a first wafer where circuits are formed and a second wafer where photosensitive elements such as photodiodes are formed are individually manufactured, and the two wafers are electrically coupled by using metal connection.

However, the above method of manufacturing the stacked image sensor has complicated production processes and high production cost. In addition, since alignment of two wafers needs to be performed at a high accuracy, the method has been used for a limited purpose.

As another example, there is a method of stacking a photosensitive element portion by using a process of depositing the photosensitive element portion on a wafer where circuits are formed. Since electrodes, gates of transistors, and metal layers on the wafer are formed through impurity doping, there is a problem in that high-temperature processes such as a crystal growing process cannot be used.

### SUMMARY OF THE INVENTION

The present invention provides a stacked image sensor including a photosensitive element portion having a photo-conductive thin film on an upper portion of a wafer where a peripheral circuit is formed.

The present invention also provides a method of manufacturing a stacked image sensor by using a simple process for depositing a photosensitive element portion having a photo-conductive thin film on a wafer where a circuit is formed.

According to an aspect of the present invention, there is provided a stacked image sensor comprising: a wafer in which a peripheral circuit is formed on an upper portion of a semiconductor substrate; and a photosensitive element portion 202 formed on an upper portion of the wafer, wherein the photosensitive element portion has a photo-conductive thin film.

According to another aspect of the present invention, there is provided a method of manufacturing a stacked image sensor, comprising: a step of forming a wafer where a peripheral circuit is formed on an upper portion of a semiconductor substrate; and a step of forming a photosensitive element portion having a photo-conductive thin film on an upper portion of the wafer.

### BRIEF DESCRIPTION OF THE DRAWINGS

FIG. 1 is a schematic circuit view illustrating a conventional stacked image sensor.

FIG. 2 is a schematic circuit view illustrating a stacked image sensor according to the present invention.

FIG. 3 is a circuit view illustrating one pixel of the stacked image sensor according to the present invention.

FIG. 4 is an equivalent circuit view illustrating one pixel of the stacked image sensor according to the present invention illustrated in FIG. 3.

FIG. 5 is a circuit view for explaining a photo-conduction phenomenon.

FIG. 6 is a view illustrating an energy band structure of FIG. 5A.

FIG. 7 is a flowchart illustrating a method of manufacturing a stacked image sensor according to the present invention.

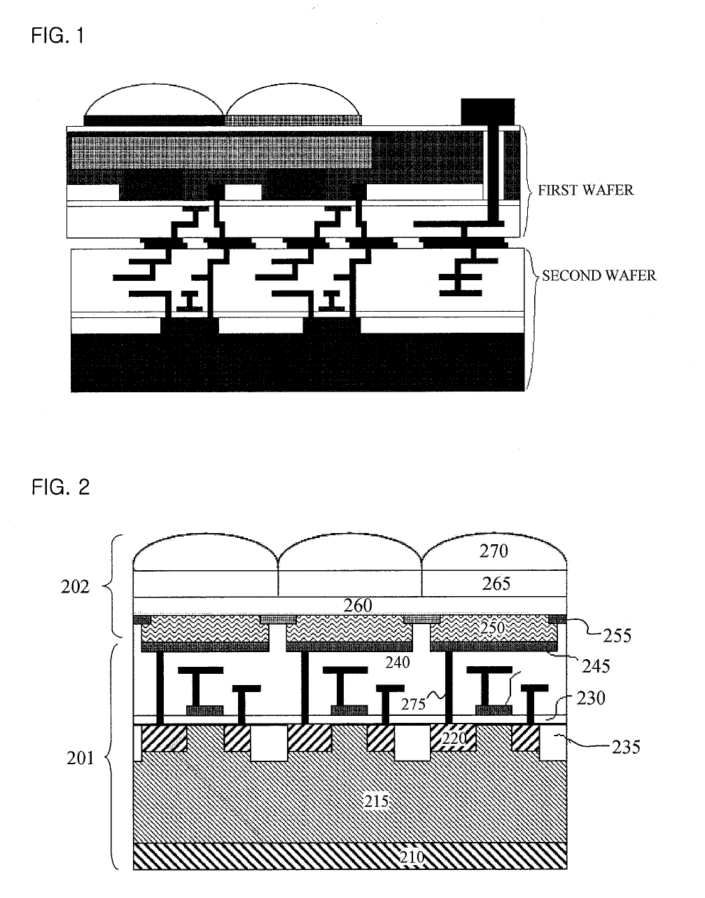

### DETAILED DESCRIPTION OF THE INVENTION

Hereinafter, embodiments of the present invention will be described in detail with reference to the accompanying drawings.

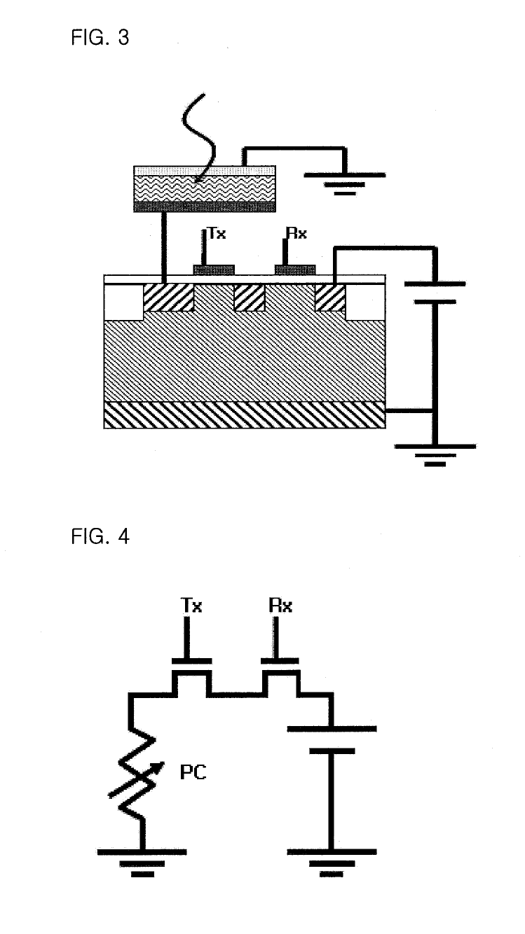

FIG. 2 is a schematic view illustrating a structure of a stacked image sensor according to the present invention.

Referring to FIG. 2, the stacked image sensor according to the present invention includes a wafer 201 where peripheral circuits are formed and a photosensitive element portion 202 formed on an upper portion of the wafer, and the photosensitive element portion 202 has a photo-conductive thin film 250.

The wafer 201 includes a first conductive type high-concentration doped semiconductor substrate 210, a first conductive type low-concentration epitaxial layer 215 formed on the semiconductor substrate, a gate oxide layer 230 formed on the epitaxial layer, one or more transistor gates 225 formed on the gate oxide layer 230, a second conductive type electrode 220 formed on an upper portion of the epitaxial layer, a trench 235 for isolation from adjacent pixels, a metal interconnection line 275 for electrical connection to the electrode and an insulating layer 240 for interlayer insulation.

The wafer 201 may be formed by using general MOS (Metal Oxide Semiconductor) processes, and thus, detailed description thereof is omitted.

The photosensitive element portion 202 having the photo-conductive thin film 250 is formed with a stacked structure on an upper portion of the wafer 201.

The photosensitive element portion 202 includes a metal pad 245 formed on an upper portion of the wafer 201, a photo-conductive thin film 250 formed on an upper portion of the metal pad, a transparent conductive oxide layer 260 formed for electrical contact on an upper portion of the photo-conductive thin film, color filters 265 formed on an upper portion of the transparent conductive oxide layer, and microlenses 270 formed on an upper portion of the color filters.

The metal pad 245 is provided so as to form the photo-conductive thin film on the wafer 201, and the metal pad is electrically connected to the wafer 201 through the metal interconnection line 275.

The photo-conductive thin film 250 is formed on the metal pad 245. As described above, the photosensitive element portion of the stacked image sensor cannot be formed by using a crystal growing method which is a high temperature process. Therefore, in the present invention, the photo-conductive thin film 250 is formed through a low temperature process using a hydrogenated amorphous silicon thin film having a good photo-conductivity.

FIG. 3 is a circuit view illustrating a structure of a one-pixel circuit of the stacked image sensor according to the present invention. FIG. 4 illustrates an equivalent circuit of one pixel of the stacked image sensor according to the present invention illustrated in FIG. 3.

In FIG. 4, a photo-conductor (PC) is a photosensitive element of which resistance varies with an amount of incident light, and Tx and Rx are MOS transistors for electrical connection to the PC. Photo sensing operation is as follows. Firstly, voltages are applied to the transistors Tx and Rx, and thus, a predetermined voltage is applied across the photosensitive element PC.

Next, the transistors Tx and Rx are turned off so as to be electrically disconnected from the photosensitive element PC. Although a voltage is applied across the photosensitive element PC, only a dark current flows through the photosensitive element PC since the photosensitive element PC has no carrier. Due to the dark current, the voltage difference between both terminals of photosensitive element PC is decreased. In a case where a hydrogenated amorphous silicon thin film is used as the photosensitive element PC, if the voltage across the photosensitive element PC is 1 volt, if an area thereof is 1 μm², and if a length thereof 1 μm, the dark current is about 10⁻¹³ A.

When light is incident to the photosensitive element PC, electrons and holes photo-charges that are generated by the incident photons are accelerated by a strong electric field, and a large amount of current can be flown in proportion to the number of absorbed photons. Therefore, when the light is incident to the photosensitive element PC, the voltage difference between both terminals of the photosensitive element PC approaches 0 in proportion to the number of generated photo-charges. Accordingly, an intensity of light absorbed by one pixel can be measured by measuring a voltage of an isolated electrode due to the electrons generated by the incident light for a predetermined time.

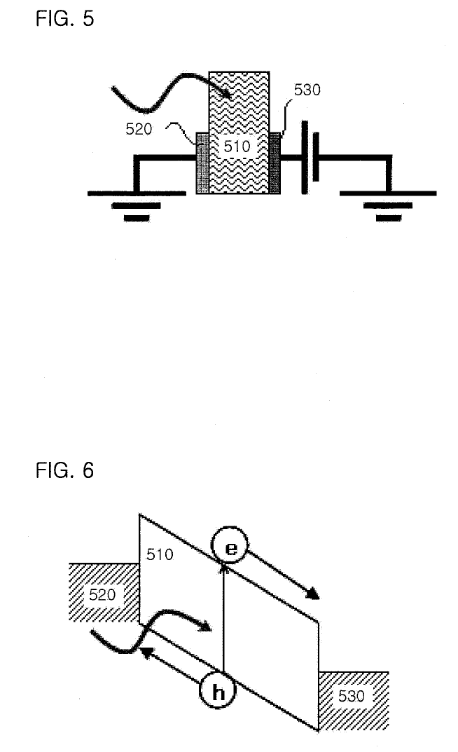

FIG. 5 is a circuit view for explaining a photo-conduction phenomenon in case of using a hydrogenated amorphous silicon, and FIG. 6 is a view illustrating an energy band structure of FIG. 5.

In general, an undoped hydrogenated amorphous silicon thin film 510 can be manufactured at a temperature of about 300° C. by using a PECVD (Plasma enhanced chemical vapor deposition) method. The undoped hydrogenated amorphous silicon has a resistivity of about 10⁹ Ω*cm. Metal electrodes 520 and 530 are disposed at the two ends of the hydrogenated amorphous silicon thin film 510, and after, a voltage is applied across the two ends. In this case, in a state that no light is incident, a small amount of current which is determined according to the resistivity is flown.

The band structure is illustrated in FIG. 5B. When photons are incident to the hydrogenated amorphous silicon thin film 510 in the state that a voltage is applied, electrons and holes are generated in the hydrogenated amorphous silicon thin film due to the incident photons. The electrons and holes are moved towards corresponding terminals by an external potential.

In general, since a light absorbance of the hydrogenated amorphous silicon thin film is about 50 times larger than that of silicon, a sufficient amount of visible light can be absorbed by the thin film having a thickness of about 4000 Å or less.

According to manufacturing methods, the hydrogenated amorphous silicon thin film has a band gap of 1.2 eV to 1.5 eV. A large number of traps exist in the band gap. Therefore, when light is incident on the hydrogenated amorphous silicon thin film under no external electric field, the electrons and holes in the electron-hole pairs are easily recombined. Accordingly, it is preferable that the external voltage is increased in order to improve photo-electric conversion efficiency in case of using the hydrogenated amorphous silicon thin film.

On the other hand, the transparent conductive oxide layer 260 for electrical contact is formed on an upper portion of the photo-conductive thin film 250. The transparent conductive oxide layer 260 may be replaced with a non-conductive oxide layer which is made of a general oxide. In addition, a partially-opened metal electrode layer 255 of which a portion is opened in a light-incident direction may be used for electrical contact to the photo-conductive thin film 250.

The color filters 265 that are formed on an upper portion of the transparent conductive oxide layer 260 provide specific colors to pixels. The microlenses 270 that are formed on an upper portion of the color filters 265 have a function of condensing the incident light on the photo-conductive thin film 250.

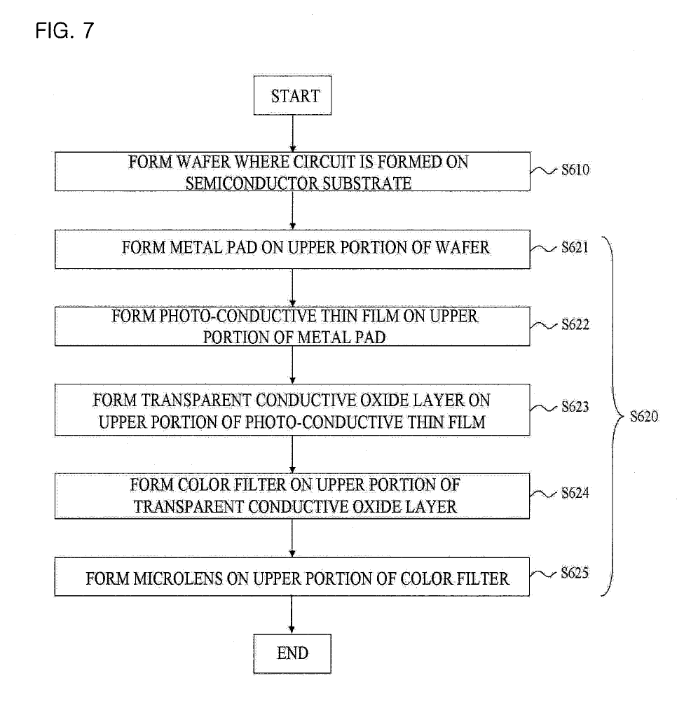

FIG. 7 is a flowchart illustrating a method of manufacturing a stacked image sensor according to the present invention.

Referring to FIG. 7, the method of manufacturing a stacked image sensor includes a step S610 of forming a wafer where a circuit is formed on a semiconductor substrate and a step S620 of forming a photosensitive element portion on an upper portion of the wafer.

The step 610 of forming a wafer includes a step of forming a first conductive type low-concentration epitaxial layer on a first conductive type semiconductor substrate, a step of forming a trench for insulation from adjacent pixels on the epitaxial layer, a step of forming a gate oxide layer on the epitaxial layer, a step of forming a second conductive type electrode on the epitaxial layer, a step of forming a transistor gate electrode on the gate oxide layer, a step of forming a metal interconnection line for electrical connection to the electrode, and a step of forming an insulating layer for interlayer insulation.

The step S601 of forming a wafer is the same as general MOS processes, and thus, detailed description thereof is omitted.

The step S620 of forming a photosensitive element portion includes a step S621 of forming a metal pad used to form the photo-conductive thin film on an upper portion of the wafer, a step S622 of forming the photo-conductive thin film on an upper portion of the metal pad, and a step S623 of forming a transparent conductive oxide layer for electrical connection to an upper portion of the photo-conductive thin film.

In the step S621 of forming the metal pad used to form the photo-conductive thin film on an upper portion of the wafer, the metal pad is electrically connected to the wafer through the metal interconnection line.

The step S622 of forming the photo-conductive thin film on an upper portion of the metal pad is a step of forming a thin film by using a hydrogenated amorphous silicon as described above. In the step, it is preferable that a process temperature is maintained to 400° C. so as not to deform an underlying metal interconnection line.

The step S623 of forming the transparent conductive oxide layer for electrical connection to an upper portion of the photo-conductive thin film may be replaced with a step of forming a non-conductive oxide layer on an upper portion of the photo-conductive thin film and forming a metal electrode layer to be electrically connected to the photo-conductive thin film.

If needed, a step S624 of forming a color filter on an upper portion of the transparent conductive oxide layer and a step S625 of forming a microlens on an upper portion of the color filter may be further included

As described above, in the method of manufacturing a stacked image sensor according to the present invention, the stacked image sensor can be manufactured through a simple process of depositing a photosensitive element portion including a hydrogenated amorphous silicon thin film on a wafer where a circuit is formed. In a stacked image sensor according to the present invention, since a wafer where a circuit is formed and a photosensitive element portion are formed in a stacked structure, a whole size of the image sensor can be reduced, and there is no optical crosstalk due to absorption of incident light to adjacent pixels. In addition, since a photo-conductive element having a high light absorbance is used, a high photo-electric conversion efficiency can be obtained.

In addition, in a method of manufacturing a stacked image sensor according to the present invention, since the upper photosensitive element can be formed by using a simple low-temperature process, a production cost can be reduced.

While the present invention has been particularly shown and described with reference to exemplary embodiments thereof, it will be understood by those skilled in the art that various changes in form and details may be made therein without departing from the spirit and scope of the present invention as defined by the appended claims.

1. A stacked image sensor comprising:
a wafer in which a peripheral circuit is formed on an upper portion of a semiconductor substrate; and
a photosensitive element portion formed on an upper portion of the wafer,
wherein the photosensitive element portion has a photo-conductive thin film.

2. The stacked image sensor of claim 1, wherein the wafer comprises:
a first conductive type high-concentration doped semiconductor substrate;
a first conductive type low-concentration epitaxial layer formed on the semiconductor substrate;
a gate oxide layer formed on the epitaxial layer;
one or more transistor gates formed on the gate oxide layer;
a second conductive type electrode formed on an upper portion of the epitaxial layer;
a trench for isolation from adjacent pixels;
a metal interconnection line for electrical connection to the electrode; and
an insulating layer for interlayer insulation.

3. The stacked image sensor of claim 1, wherein the photosensitive element portion comprises:
a metal pad formed on an upper portion of the wafer;
a photo-conductive thin film formed on an upper portion of the metal pad;
a transparent conductive oxide layer formed for electrical contact on an upper portion of the photo-conductive thin film;
a color filter formed on an upper portion of the transparent conductive oxide layer; and
a microlens formed on an upper portion of the color filter.

4. The stacked image sensor of claim 3, wherein the metal pad is electrically connected to the wafer through the metal interconnection line.

5. The stacked image sensor of claim 3, wherein the photo-conductive thin film is a hydrogenated amorphous silicon thin film.

6. The stacked image sensor of claim 1, wherein the photosensitive element portion comprises:
a metal pad formed on an upper portion of the wafer;
a photo-conductive thin film fanned on an upper portion of the metal pad;
a non-conductive oxide layer formed on an upper portion of the photo-conductive thin film;
a metal electrode layer electrically connected to the photo-conductive thin film;
a color filter formed on an upper portion of the non-conductive oxide layer; and
a microlens formed on an upper portion of the color filter.

7. A method of manufacturing a stacked image sensor, comprising:
a step of forming a wafer where a peripheral circuit is formed on an upper portion of a semiconductor substrate; and
a step of forming a photosensitive element portion having a photo-conductive thin film on an upper portion of the wafer.

8. The method of claim 7, wherein the step of forming a wafer comprises:
a step of forming a first conductive type low-concentration epitaxial layer on a first conductive type semiconductor substrate;
a step of forming a trench for insulation from adjacent pixels on the epitaxial layer;
a step of forming a gate oxide layer on the epitaxial layer;
a step of forming a second conductive type electrode on the epitaxial layer;
a step of forming a transistor gate electrode on the gate oxide layer;
a step of forming a metal interconnection line for electrical connection to the electrode; and
a step of forming an insulating layer for interlayer insulation.

9. The method of claim 7, wherein the step of forming a photosensitive element portion comprises:
a step of forming a metal pad used to forming the photo-conductive thin film on an upper portion of the wafer;
a step of forming the photo-conductive thin film on an upper portion of the metal pad; and
a step of forming a transparent conductive oxide layer for electrical connection to an upper portion of the photo-conductive thin film.

10. The method of claim 7, wherein the step of forming the photosensitive element portion comprises:
a step of forming a metal pad used to form the photo-conductive thin film on an upper portion of the wafer;
a step of forming the photo-conductive thin film on an upper portion of the metal pad; and
a step of forming a non-conductive oxide layer on an upper portion of the photo-conductive thin film and forming a metal electrode layer to be electrically connected to the photo-conductive thin film.

11. The method of claim 9, wherein the step of forming the photosensitive element portion further comprises:
a step of forming a color filter on an upper portion of the transparent conductive oxide layer; and
a step of forming a microlens on an upper portion of the color filter.

12. The method of claim 9, wherein the step of forming the photo-conductive thin film is performed by using a hydrogenated amorphous silicon.

13. The method of claim 10, wherein the step of forming the photosensitive element portion further comprises:
a step of forming a color filter on an upper portion of the transparent conductive oxide layer; and
a step of forming a microlens on an upper portion of the color filter.

14. The method of claim 10, wherein the step of forming the photo-conductive thin film is performed by using a hydrogenated amorphous silicon.
